(19) United States
(12) Patent Application Publication
(10) Pub. No.: US 2009/0289732 A1
(43) Pub. Date: Nov. 26, 2009

(54) SEMICONDUCTOR INTEGRATED CIRCUIT DEVICE AND FREQUENCY SYNTHESIZER

(75) Inventor: Daisuke MIYASHITA, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/434,807

(22) Filed: May 4, 2009

(30) Foreign Application Priority Data
May 23, 2008 (JP) 2008-135644

(51) Int. Cl. H03B 5/18

(52) U.S. Cl. 331/117 FE

(57) ABSTRACT

A semiconductor integrated circuit includes: a resonance circuit configured to determine an oscillation frequency; a first MOS transistor connected to the resonance circuit and configured to constitute an oscillation unit for delivering an oscillation output having the oscillation frequency; a second MOS transistor connected in parallel with the first MOS transistor; and a control unit configured to turn on and off the second MOS transistor according to the oscillation frequency, thereby enabling an equivalent gate width based on the first and second MOS transistors to be increased and decreased. Consequently, there is obtained an oscillation output having reduced phase noise, while an adequate oscillation margin is maintained.

This application is based upon and claims the benefit of priority from the prior Japanese Patent Application No. 2008-135644 filled in Japan on May 23, 2008; the entire contents of which are incorporated herein by reference.

### BACKGROUND OF THE INVENTION

1. Field of the Invention

The present invention relates to a semiconductor integrated circuit device and a frequency synthesizer suitable for a wireless system and the like configured to generate a plurality of oscillation outputs using a voltage-controlled oscillator.

2. Description of Related Art

Conventionally, in a wireless system such as a mobile phone, a plurality of oscillation outputs of a local oscillator are generated using a frequency synthesizer which uses a PLL (phase-locked loop) circuit or the like. A VCO (voltage-controlled oscillator) is employed in the PLL circuit or the like, so that an oscillation frequency can be controlled easily.

That is, an oscillation output can be obtained by controlling the oscillation frequency of the VCO using the PLL circuit. An oscillation output having a reference frequency (reference oscillation output) from a quartz oscillator and the output of the VCO are supplied to a phase comparator constituting the PLL circuit. The phase comparator determines a phase difference between the reference oscillation output and the oscillation output of the VCO, and supplies an output based on the phase difference to the VCO through a low-pass filter as a control voltage. Thus, the oscillation output having the reference frequency is obtained from the VCO. In addition, by frequency-dividing the output of the VCO using a frequency divider and supplying the output to the phase comparator, it is possible to obtain an oscillation output having a frequency division-number times the reference frequency from the VCO.

The VCO is composed of an LC resonance circuit provided with a varactor and an oscillation transistor for power supply. The LC resonance circuit has a resonance frequency based on the varactor and a fixed inductor, and the oscillation transistor makes available an oscillation output having the resonance frequency from the LC resonance circuit. It is not possible, however, to obtain a precise oscillation frequency due to a variation in elements constituting the VCO. Hence, using a PLL circuit, a control voltage for controlling the VCO is generated on the basis of a phase difference between the reference oscillation output and the VCO output. Then, by changing the capacitance value of the varactor using this control voltage, the oscillation frequency of the VCO is fine-adjusted so as to agree with a frequency corresponding to the reference frequency.

The variable range of frequencies in accordance with a change in the capacitance of the varactor is comparatively narrow, however. If a wide variable range of frequencies is necessary, a variable capacitor is provided in the LC resonance circuit in addition to the varactor, and the oscillation frequency of the VCO is coarse-adjusted by controlling the capacitance value of the variable capacitor.

Note that if the VCO has been integrated into an IC, the variable capacitor is, in some cases, composed of a combination of a plurality of fixed capacitors and a plurality of switches. This configuration is applied in order to determine the capacitance of the LC resonance circuit as a whole by connecting a plurality of series circuits composed of switches and fixed capacitors in parallel with the varactor and turning on a specific switch or switches. Also note that MOS transistors are often employed as the switches.

On the other hand, in such a VCO as described above, the magnitude of a capacitance component constituting the LC resonance circuit greatly differs between high and low oscillation frequencies. Consequently, phase noise characteristics vary significantly depending on the frequency and degrade remarkably as the oscillation frequency becomes higher.

In contrast, Japanese Patent Application Laid-Open Publication No. 2004-527982 discloses a technique to reduce phase noise by switching a MOSFET to be connected to a tank circuit between low and high frequencies.

However, the technique proposed in the above-described publication has been problematic in that a current flow varies between low and high frequencies and power is consumed uselessly at high frequencies.

### BRIEF SUMMARY OF THE INVENTION

A semiconductor integrated circuit device in accordance with one aspect of the present invention includes: a resonance circuit configured to determine an oscillation frequency; a first MOS transistor connected to the resonance circuit and configured to constitute an oscillation unit for delivering an oscillation output having the oscillation frequency; a second MOS transistor connected in parallel with the first MOS transistor; and a control unit configured to turn on and off the second MOS transistor according to the oscillation frequency, thereby enabling an equivalent gate width based on the first and second MOS transistors to be increased and decreased.

In addition, a frequency synthesizer in accordance with one aspect of the present invention includes: a voltage-controlled oscillator composed of a resonance circuit having a resonance frequency based on the capacitance of a variable-capacitance unit which varies according to information including an oscillation frequency and of an oscillation unit including oscillation transistors connected to the resonance circuit and configured to output an oscillation output having the resonance frequency; and a control unit configured to be provided with oscillation frequency information to be supplied to a PLL circuit configured to generate information including the oscillation frequency on the basis of the output of the voltage-controlled oscillator and the oscillation frequency information, so as to variable-control the gate widths of the oscillation transistors constituting the oscillation unit.

### BRIEF DESCRIPTION OF THE DRAWINGS

FIG. 1 is a block diagram showing a semiconductor integrated circuit device in accordance with a first embodiment of the present invention;

FIG. 2 is a circuit diagram showing a configuration of a regular voltage-controlled oscillator integrated into an IC;

FIG. 3 is a graph in which an oscillation frequency is plotted on the horizontal axis and phase noise is plotted on the vertical axis to show a relationship between the oscillation frequency and the phase noise in the voltage-controlled oscillator of FIG. 2;

FIG. 4 is a circuit diagram showing a second embodiment of the present invention;

FIG. 5 is a circuit diagram showing another example of the on-off control of transistors M3 and M4;

FIG. 6 is a circuit diagram showing an example of modification;

FIG. 7 is another circuit diagram showing an example of modification; and

FIG. 8 is a block diagram showing a third embodiment of the present invention.

### DETAILED DESCRIPTION OF THE INVENTION

Hereinafter, embodiments of the present invention will be described in detail with reference to the accompanying drawings.

### First Embodiment

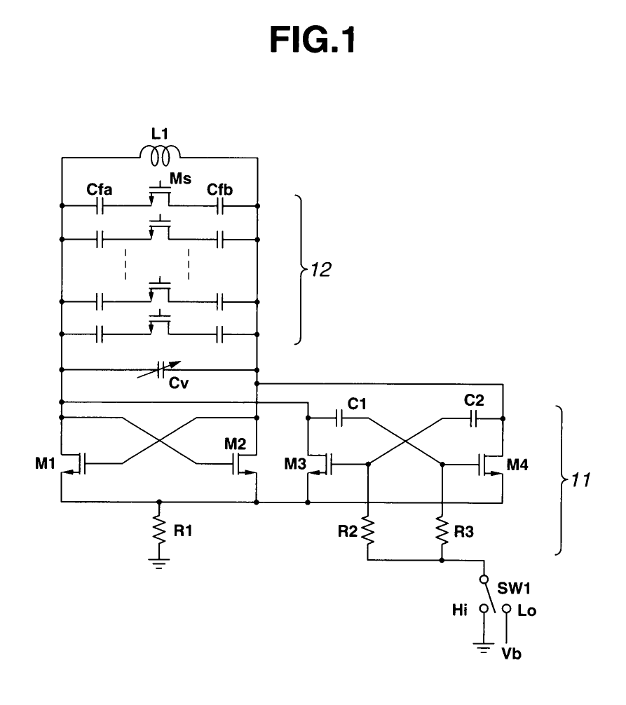

FIG. 1 is a block diagram showing a semiconductor integrated circuit device in accordance with a first embodiment of the present invention.

The semiconductor integrated circuit device of FIG. 1 constitutes a voltage-controlled oscillator. In FIG. 1, the voltage-controlled oscillator is composed of a coil L1, a variable-capacitance element Cv, such as a varactor, a variable-capacitance unit 12, and an oscillation unit 11. The variable-capacitance unit 12 is configured by parallel-connecting a plurality of variable capacitances composed of series-connected fixed capacitances Cfa and Cfb and MOS transistors Ms constituting switches. Each variable capacitance of the variable-capacitance unit 12 is connected in parallel with the coil L1, along with the variable-capacitance element Cv.

One end of the coil L1 is connected to the drain of an NMOS transistor M1 constituting the oscillation unit 11 and the other end of the coil L1 is connected to the drain of an NMOS transistor M2 constituting the oscillation unit 11. The sources of the transistors M1 and M2 forming a differential pair are common-connected to each other, and the connection point of the sources is connected to a reference potential point through a resistor R1. The drain of the transistor M1 is connected to the gate of the transistor M2, and the drain of the transistor M2 is connected to the gate of the transistor M1.

In addition, in the present embodiment, a differential pair of NMOS transistors M3 and M4 is provided in the oscillation unit 11. The transistors M3 and M4 are respectively provided in parallel with the transistors M1 and M2. That is, the drain of the transistor M1 is common-connected to the drain of the transistor M3, and the source of the transistor M1 is common-connected to the source of the transistor M3. Likewise, the drain of the transistor M2 is common-connected to the drain of the transistor M4, and the source of the transistor M2 is common-connected to the source of the transistor M4.

The drain of the transistor M1 is connected to the gate of the transistor M4 through a capacitor C1, and the drain of the transistor M2 is connected to the gate of the transistor M3 through a capacitor C2. The gates of the transistors M3 and M4 are connected to a switch SW1 through resistors R2 and R3, respectively. The switch SW1 serving as a control unit selects a terminal Hi if an oscillation frequency is high, thereby supplying a reference potential to the gates of the transistors M3 and M4 through the resistors R2 and R3. If the oscillation frequency is low, the switch SW1 selects a terminal Lo, thereby supplying a predetermined gate potential Vb to the gates of the transistors M3 and M4 through the resistors R2 and R3.

Consequently, the transistors M3 and M4 are turned off if the oscillation frequency is high, and are turned on if the oscillation frequency is low. Note that a potential from the switch SW1 is prevented by the capacitors C1 and C2 from being supplied to the gates of the transistors M1 and M2. Thus, it is possible to on/off-control only the transistors M3 and M4 using the switch SW1. In addition, in a high-frequency sense, the gates of the transistors M3 and M4 are connected to the gates of the transistors M1 and M2, respectively.

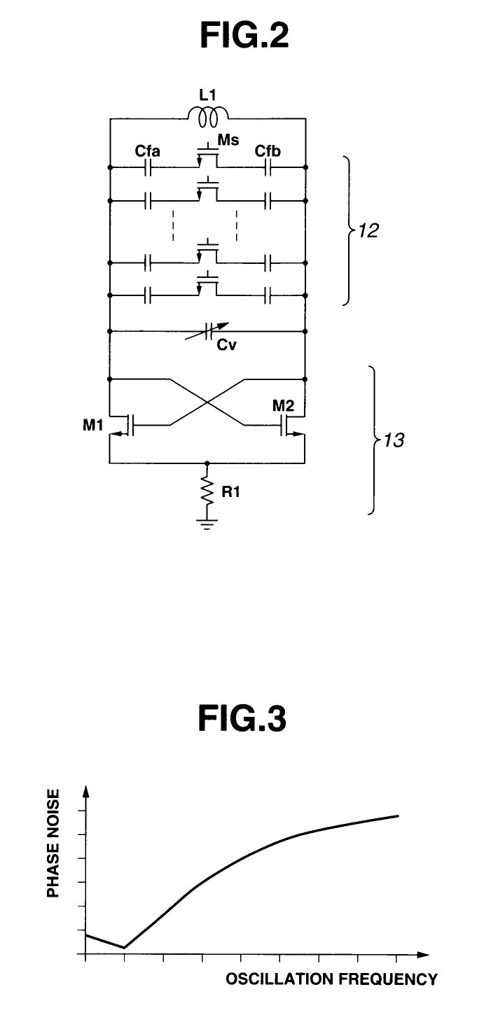

FIG. 2 is a circuit diagram showing a configuration of a regular voltage-controlled oscillator integrated into an IC.

The circuit of the present embodiment shown in FIG. 1 differs from the circuit of FIG. 2 in that the oscillation unit 11 is employed in place of an oscillation unit 13 of FIG. 2. The oscillation unit 13 is composed only of a differential pair of NMOS transistors M1 and M2.

The oscillation frequencies of the voltage-controlled oscillators shown in FIGS. 1 and 2 are determined by an LC resonance circuit composed of the coil L1, the variable-capacitance element Cv, and the variable-capacitance unit 12. Assuming that the inductance of the coil L1 is “L1”, the capacitance value of the variable-capacitance element Cv is “Cv”, the capacitance values of the respective variable capacitances based on the fixed capacitances Cfa and Cfb of the variable-capacitance unit 12 are “Cf1”, “Cf2”, . . . , then an oscillation frequency “f” is given by formula (1) shown below:

$$f = \frac{1}{2 π \sqrt{L 1 ( Cv + Cf 1 + Cf 2 + …}} \qquad ( 1 )$$

Note that the capacitance values “Cf1”, “Cf2”, . . . , of the respective variable capacitances of the variable-capacitance unit 12 are generated only when a transistor Ms constituting each variable capacitance is on. Consequently, it is possible to control an oscillation frequency by on/off-controlling the transistors Ms constituting the respective variable capacitances and, thereby, changing the capacitance value of the variable-capacitance unit 12 as a whole.

FIG. 3 is a graph in which an oscillation frequency is plotted on the horizontal axis and phase noise is plotted on the vertical axis to show a relationship between the oscillation frequency and the phase noise in the voltage-controlled oscillator of FIG. 2. As shown in FIG. 3, the phase noise varies according to the oscillation frequency and, thus, the voltage-controlled oscillator of FIG. 2 has the disadvantage that the phase noise increases as the oscillation frequency becomes higher.

The phase noise is considered to arise when currents flowing through the oscillation transistors M1 and M2 vary according to, for example, the characteristics of any one or more elements constituting the voltage-controlled oscillator and, therefore, an oscillation amplitude varies, and that the amplitude variation is converted into a phase variation due to the nonlinearity of capacitance.

The capacitance of the LC resonance circuit includes not only the capacitances of the variable-capacitance element Cv and the respective fixed capacitances Cfa and Cfb of the variable-capacitance unit 12, but also the parasitic capacitances of the MOS transistors Ms constituting switches and the oscillation transistors M1 and M2. The parasitic capacitance of a MOS transistor (gate capacitance) is dependent on a gate-source voltage and is nonlinear. Assuming that the coil L1 is composed of a passive element and, therefore, the inductance L1 thereof is linear, then the nonlinearity of the capacitance of the LC resonance circuit is greatly affected by the nonlinearity of the parasitic capacitance of the MOS transistor. This means that phase noise arising in an oscillation output deteriorates with an increase in the nonlinearity of capacitance.

Since each variable capacitance of the variable-capacitance unit 12 is composed of fixed capacitances Cfa and Cfb, which are passive elements, and a MOS transistor Ms, it is relatively easy to suppress nonlinearity. In contrast, the nonlinearity of the parasitic capacitance of an oscillation transistor is affected by a gate-source voltage and the like and is, therefore, comparatively large.

Incidentally, the linearity of a transistor generally improves in proportion to an overdrive voltage (Vg-Vth, where “Vg” is a gate voltage and “Vth” is a threshold voltage). The overdrive voltage satisfies formula (2) shown below:

$$Vg - Vth ∝ \sqrt{\frac{IL}{W}} \qquad ( 2 )$$

where, “I” is a current, “L” is a gate length, and “W” is a gate width.

As is evident from this formula (2), it is possible to improve linearity by increasing the current or reducing “W/L”. Since power consumption increases if the current is increased, it is preferable to reduce “W/L”. If “W/L” is reduced, however, the transconductance of the transistor is also reduced. If a large number of fixed capacitances Cfa and Cfb are connected by turning on the respective transistors Ms of the variable-capacitance unit 12, the loss of the LC resonance circuit becomes larger. Hence, the transconductance of the oscillation transistor must be made larger in order to make oscillation possible. Thus, it is not possible to reduce “W/L”.

However, as shown in formula (1) above, a large number of fixed capacitances Cfa and Cfb having small nonlinearity are used if the oscillation frequency is low. Thus, the ratio of the nonlinear parasitic capacitances of the oscillation transistors M1 and M2 to the total capacitance decreases and, therefore, the nonlinearity of the LC resonance circuit as a whole also decreases. Accordingly, the deterioration of phase noise is considered to be small. On the other hand, if the oscillation frequency is high, the ratio of the highly-nonlinear parasitic capacitances of the oscillation transistors to the total capacitance increases and, therefore, the nonlinearity of the LC resonance circuit as a whole also increases. Thus, the phase noise deteriorates. In this case, however, there is no need to increase the transconductance of the oscillation transistors since fewer fixed capacitances Cfa and Cfb are connected to the LC resonance circuit.

Hence, in the present embodiment, the generation of phase noise is suppressed by enabling the “W/L” of oscillation transistors to vary between high and low oscillation frequencies, while ensuring required transconductance.

As described above, the source and drain of the transistor M3 are respectively connected to the source and drain of the transistor M1. Likewise, the source and drain of the transistor M4 are respectively connected to the source and drain of the transistor M2. In addition, in a high-frequency sense, the gates of the transistors M3 and M4 are respectively connected to the gates of the transistors M1 and M2. Consequently, when the transistors M3 and M4 are on, the present embodiment is equivalent to a case in which the oscillation unit 11 is composed of a transistor having a gate width equivalent to a sum of the gate widths of the transistors M1 and M2 and the gate widths of the transistors M3 and M4.

That is, when the transistors M3 and M4 are off, the transconductance is determined by the gate widths of the transistors M1 and M2. In contrast, when the transistors M3 and M4 are on, the transconductance is determined on the basis of a gate width equivalent to a sum of the gate widths of the transistors M1 and M2 and the gate widths of the transistors M3 and M4.

Next, an explanation will be made of the operation of an embodiment configured in such a manner as described above.

Now assume that the transistors Ms are turned on and a comparatively large number of fixed capacitances Cfa and Cfb are connected to the LC resonance circuit, thereby setting the oscillation frequency low. In this case, the switch SW1 supplies a gate potential “Vb” to the gates of the transistors M3 and M4 to turn on the transistors M3 and M4.

Since a large number of fixed capacitances Cfa and Cfb are connected to the LC resonance circuit in this case, the deterioration of phase noise is relatively small, as described above.

On the other hand, an equivalent gate width increases as the result of the transistors M3 and M4 being turned on. Thus, an oscillation margin increases since the transconductance is large. Consequently, it is possible to reliably cause oscillation to take place even if a large number of fixed capacitances Cfa and Cfb are connected to the LC resonance circuit.

On the contrary, assume that the transistors Ms are turned off and the number of fixed capacitances Cfa and Cfb to be connected to the LC resonance circuit is reduced, thereby setting the oscillation frequency high. In this case, the switch SW1 supplies a reference potential to the gates of the transistors M3 and M4 to turn off the transistors M3 and M4.

Since a few fixed capacitances Cfa and Cfb are connected to the LC resonance circuit, it is possible to reliably cause oscillation to take place even if the transconductance is small. In addition, since the transistors M3 and M4 are off, the gate width decreases to a small value based on the gate widths of only the transistors M1 and M2. Thus, it is possible to improve linearity and suppress the deterioration of phase noise.

As described above, in the present embodiment, one of the two differential pairs of oscillation transistors are on/off-controlled to make the gate widths of the oscillation transistors variable in an equivalent manner. If the oscillation frequency is high, one differential pair of oscillation transistors is turned off to decrease the effective gate widths of the oscillation transistors, thereby improving linearity. On the contrary, if the oscillation frequency is low, one differential pair of oscillation transistors is turned on to increase the effective gate widths, thereby increasing the transconductance. Consequently, it is possible to obtain an adequate oscillation margin and reduce phase noise, irrespective of the oscillation frequency.

### Second Embodiment

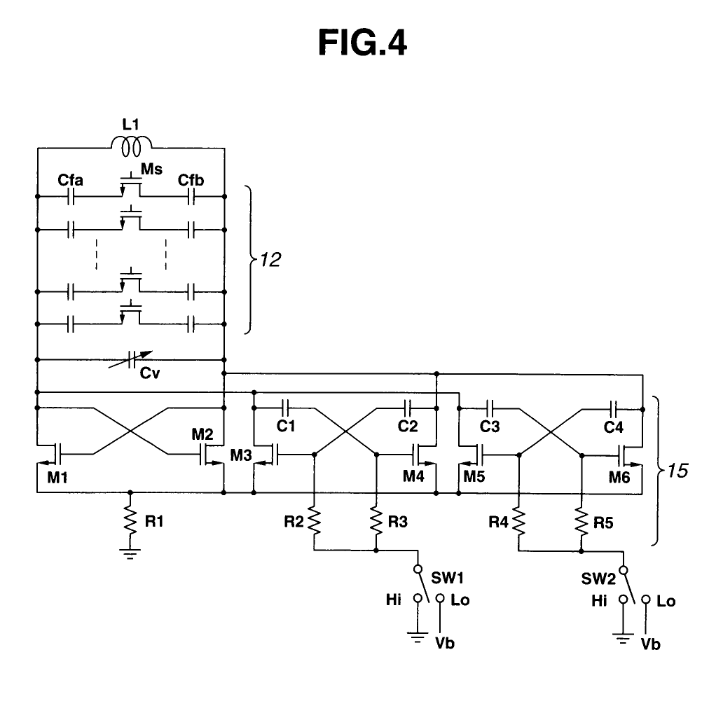

FIG. 4 is a circuit diagram showing a second embodiment of the present invention. In FIG. 4, components same as those of FIG. 1 are denoted by the same reference symbols and will not be explained again. The present embodiment differs from the first embodiment in that an oscillation unit 15 is employed in place of the oscillation unit 11.

The oscillation unit 15 differs from the oscillation unit 11 in that there is added a differential pair of NMOS transistors M5 and M6. The transistor M5 is provided in parallel with the transistors M1 and M3, and the transistor M6 is provided in parallel with the transistors M2 and M4. That is, the drain of the transistor M5 is common-connected to the drains of the transistors M1 and M3, and the source of the transistor M5 is common-connected to the sources of the transistors M1 and M3. Likewise, the drain of the transistor M6 is common-connected to the drains of the transistors M2 and M4, and the source of the transistor M6 is common-connected to the sources of the transistors M2 and M4.

The drain of the transistor M1 is connected to the gate of the transistor M6 through a capacitor C3, and the drain of the transistor M2 is connected to the gate of the transistor M5 through a capacitor C4. The gates of the transistors M5 and M6 are connected to a switch SW2 through resistors R4 and R5, respectively. The switch SW2 selects a terminal Hi if the oscillation frequency is high, and supplies a reference potential to the gates of the transistor M5 and M6 through the resistors R4 and R5. The switch SW2 selects a terminal Lo if the oscillation frequency is low, and supplies a predetermined gate potential Vb to the gates of the transistor M5 and M6 through the resistors R4 and R5.

Consequently, the transistors M5 and M6 are off if the oscillation frequency is high, and are on if the oscillation frequency is low. Note that a potential from the switch SW2 is prevented by the capacitors C3 and C4 from being supplied to the gates of the transistors M1 to M4. Thus, it is possible to on/off-control only the transistors M5 and M6 using the switch SW2. In addition, in a high-frequency sense, the gates of the transistors M5 and M6 are respectively connected to the gates of the transistors M1 and M2.

In the present embodiment configured in such a manner as described above, the switches SW1 and SW2 are controlled according to the oscillation frequency. As in the first embodiment, the transistors M3 to M6 are turned on if the switches SW1 and SW2 select the terminal Lo and, therefore, an equivalent gate width increases. Thus, it is possible to increase an oscillation margin even if the loss of the LC resonance circuit is large. On the contrary, the transistors M3 to M6 are turned off if the switches SW1 and SW2 select the terminal Hi and, therefore, the equivalent gate width decreases. Thus, it is possible to improve linearity and suppress the deterioration of phase noise.

Since the present embodiment includes three differential pairs, the equivalent gate width can be controlled in three or four steps. Now assume that the gate widths of the transistors M1 and M2 are “W1”. Also assume that the gate widths of the transistors M3 and M4 and the gate widths of the transistors M5 and M6 are equal to each other and defined as “W2”. In this case, the gate width is made equal to “W1” by controlling the switches SW1 and SW2 so as to turn on only the transistors M1 and M2. Furthermore, the equivalent gate width can be made equal to “W1”+“W2” by controlling the switches SW1 and SW2 so as to turn on only the transistors M1 to M4. Still furthermore, the equivalent gate width can be made equal to “W1”+“W2”+“W3” by controlling the switches SW1 and SW2 so as to turn on the transistors M1 to M6.

Alternatively, assume that the gate widths of the transistors M1 and M2 are “W1”, the gate widths of the transistors M3 and M4 are “W2”, and the gate widths of the transistors M5 and M6 are “W3” (W3>W2). In this case, the gate width is made equal to “W1” by controlling the switches SW1 and SW2 so as to turn on only the transistors M1 and M2. Furthermore, the equivalent gate width can be made equal to “W1”+“W2” by controlling the switches SW1 and SW2 so as to turn on only the transistors M1 to M4. Still furthermore, the equivalent gate width can be made equal to “W1”+“W3” by controlling the switches SW1 and SW2 so as to turn on the transistors M1, M2, M5 and M6. Yet still furthermore, the equivalent gate width can be made equal to “W1”+“W2”+“W3” by controlling the switches SW1 and SW2 so as to turn on the transistors M1 to M6.

As described above, in the present embodiment, it is possible to change the equivalent gate width in three or four steps. Thus, even more elaborate control can be performed according to the oscillation frequency.

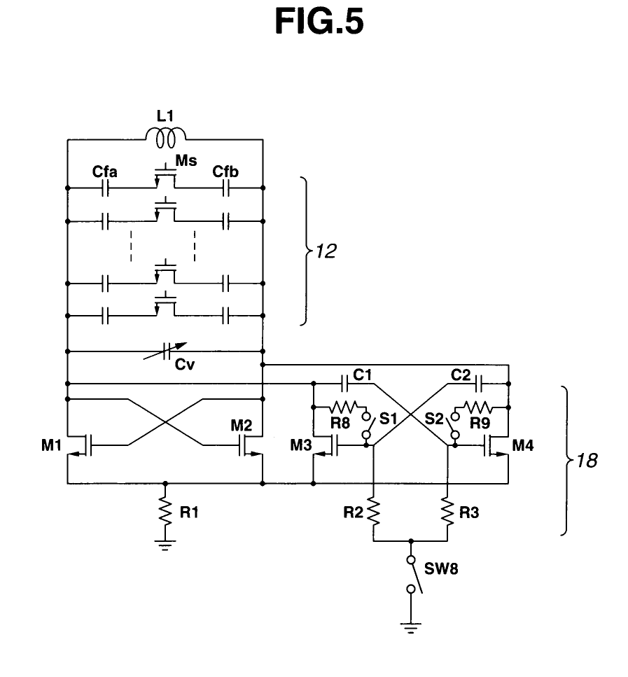

FIG. 5 is a circuit diagram showing another example of the on-off control of transistors M3 and M4. In FIG. 5, components same as those of FIG. 1 are denoted by the same reference symbols and will not be explained again. FIG. 5 differs from FIG. 1 in that resistors R8 and R9 and switches S1 and S2 are added and in that an oscillation unit 18 in which a switch SW8 is employed in place of the switch SW1 is used.

The drain of the transistor M3 is connected to the gate of the transistor M3 through the resistor R8 and the switch S1. Likewise, the drain of the transistor M4 is connected to the gate of the transistor M4 through the resistor R9 and the switch S2. In addition, the gate of the transistor M3 is connected to a reference potential point through the resistor R2 and the switch SW8. Likewise, the gate of the transistor M4 is connected to the reference potential point through the resistor R3 and the switch SW8.

If the oscillation frequency is comparatively high, the switch SW8 is on and the switches S1 and S2 are off. Alternatively, if the oscillation frequency is comparatively low, the switch SW8 is off and the switches S1 and S2 are on. If the switch SW8 is on and the switches S1 and S2 are off, then the transistors M3 and M4 are off and, therefore, the equivalent gate width decreases. Thus, it is possible to improve linearity and suppress the deterioration of phase noise even if the oscillation frequency is high. If the switch SW8 is off and the switches S1 and S2 are on, then the transistors M3 and M4 are on and, therefore, the equivalent gate width increases. Thus, it is possible to increase an oscillation margin even if the oscillation frequency is low and the loss of the LC resonance circuit is large.

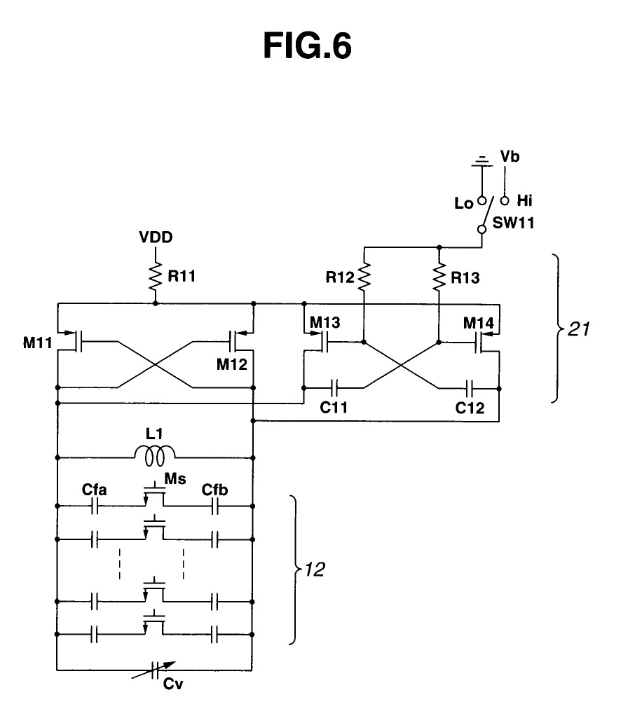

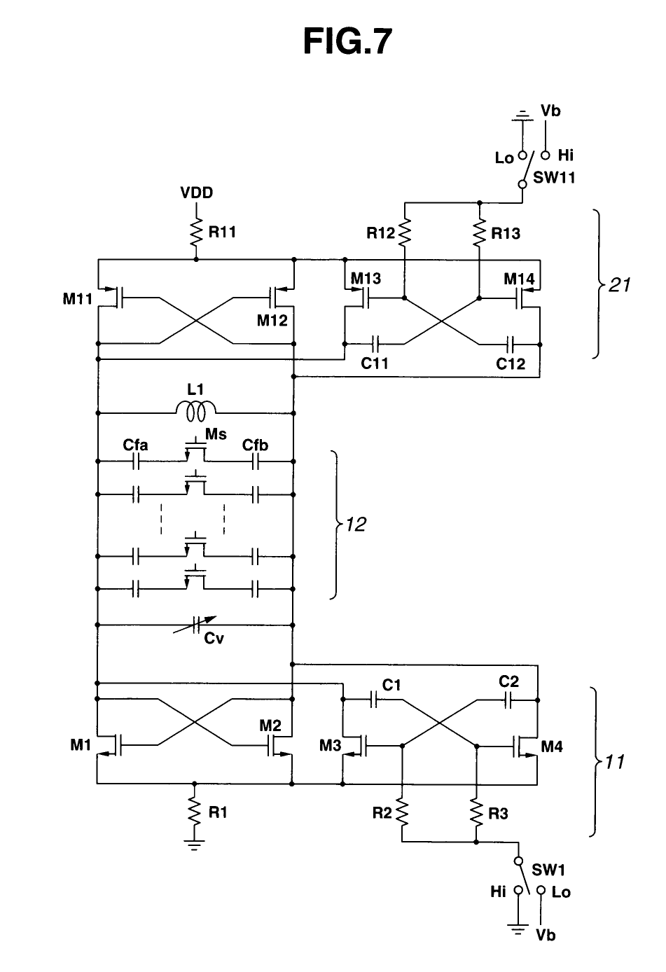

FIGS. 6 and 7 are circuit diagrams showing examples of modification. In FIGS. 6 and 7, components same as those of FIG. 1 are denoted by the same reference symbols and will not be explained again.

In FIGS. 1 and 4, examples have been shown in which NMOS transistors are employed as the oscillation transistors of an oscillation unit. In contrast, FIG. 6 shows an example in which PMOS transistors are employed as the oscillation transistors of the oscillation unit. The oscillation unit 21 of FIG. 6 differs from the oscillation unit 11 of FIG. 1 in that PMOS transistors M11 to M14 are employed in place of the NMOS transistors M1 to M4, resistors R11 to R13 are employed in place of the resistors R1 to R3, capacitors C11 and C12 are employed in place of the capacitors C1 and C2, and a switch SW11 is employed in place of the switch SW1.

If the switch SW11 selects the terminal Lo, then the transistors M13 and M14 are turned on and, therefore, an equivalent gate width increases. Thus, it is possible to increase an oscillation margin even if the loss of the LC resonance circuit is large. On the contrary, if the switch SW12 selects the terminal Hi, then the transistors M13 and M14 are turned off and, therefore, the equivalent gate width decreases. Thus, it is possible to improve linearity and suppress the deterioration of phase noise.

In addition, FIG. 7 shows an example in which CMOS transistors composed of NMOS transistors and PMOS transistors are employed as the oscillation transistors of the oscillation unit. Note that in the example of FIG. 7, the switches SW1 and SW11 operate in conjunction with each other to simultaneously select the terminal Lo or the terminal Hi.

Also note that if the oscillation transistors are composed of CMOS transistors, it is possible to change the equivalent gate width by turning on one of NMOS and PMOS transistors and turning off the other transistor according to an oscillation frequency, when compared with a case in which both transistors are turned on and off.

### Third Embodiment

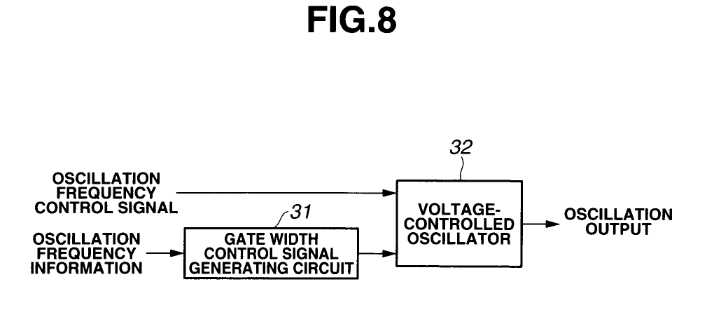

FIG. 8 is a block diagram showing a third embodiment of the present invention.

Oscillation frequency information is input to a gate width control signal generating circuit 31, whereas an oscillation frequency control signal is input to a voltage-controlled oscillator 32. The voltage-controlled oscillator 32 is configured using one of semiconductor integrated circuit devices in accordance with the above-described respective embodiments. The oscillation frequency control signal is used to on/off-control the MOS transistors Ms of the variable-capacitance unit 12. With the oscillation frequency control signal, it is possible to control the oscillation frequency of the voltage-controlled oscillator 32. Note that by allowing the oscillation frequency control signal to be independently supplied to each transistor Ms, it is possible to control the respective transistors Ms independently of each other, thereby enabling oscillation to take place at an arbitrary oscillation frequency.

The oscillation frequency information includes information on the oscillation frequency of the voltage-controlled oscillator 32 to be controlled by a oscillation frequency control signal. The gate width control signal generating circuit 31 generates a gate width control signal on the basis of the oscillation frequency information and outputs the signal to the voltage-controlled oscillator 32. The gate width control signal is used to control the switches SW1, SW2, SW8 and SW11 in each of the above-described embodiments. Consequently, it is possible to change the equivalent gate width of an oscillation unit according to the oscillation frequency of the voltage-controlled oscillator 32.

That is, if the oscillation frequency of the voltage-controlled oscillator 32 is comparatively low, it is possible to increase an oscillation margin by increasing the equivalent gate width, even if the loss of the LC resonance circuit is large. On the contrary, if the oscillation frequency of the voltage-controlled oscillator 32 is comparatively high, it is possible to improve linearity and suppress the deterioration of phase noise by decreasing the equivalent gate width.

Note that in a frequency synthesizer device provided with a PLL circuit and a voltage-controlled oscillator, oscillation frequency information is supplied to the PLL circuit to generate an oscillation frequency control signal from the PLL circuit. Accordingly, by providing the oscillation frequency information to be supplied to the PLL circuit also to the gate width control signal generating circuit 31, it is possible to also apply the present invention to the frequency synthesizer device.

Having described the preferred embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A semiconductor integrated circuit device comprising:
a resonance circuit configured to determine an oscillation frequency;
a first MOS transistor connected to the resonance circuit and configured to constitute an oscillation unit for delivering an oscillation output having the oscillation frequency;
a second MOS transistor connected in parallel with the first MOS transistor; and
a control unit configured to turn on and off the second MOS transistor according to the oscillation frequency, thereby enabling an equivalent gate width based on the first and second MOS transistors to be increased and decreased.

2. The semiconductor integrated circuit device according to claim 1, wherein the first and second MOS transistors are configured to form a differential pair along with third and fourth MOS transistors, respectively.

3. The semiconductor integrated circuit device according to claim 1, wherein the resonance circuit includes an inductor and a variable-capacitance unit the capacitance of which varies according to information including an oscillation frequency.

4. The semiconductor integrated circuit device according to claim 2, wherein the resonance circuit includes an inductor and a variable-capacitance unit the capacitance of which varies according to information including an oscillation frequency.

5. The semiconductor integrated circuit device according to claim 3, wherein the variable-capacitance unit is configured by parallel-connecting a plurality of series circuits composed of first capacitances and switches.

6. The semiconductor integrated circuit device according to claim 4, wherein the variable-capacitance unit is configured by parallel-connecting a plurality of series circuits composed of first capacitances and switches.

7. The semiconductor integrated circuit device according to claim 1, wherein the drain of the second MOS transistor is connected to the drain of the first MOS transistor, the source of the second MOS transistor is connected to the source of the first MOS transistor, and the gate of the second MOS transistor is connected to the gate of the first MOS transistor through a second capacitance element.

8. The semiconductor integrated circuit device according to claim 2, wherein the drain of the second MOS transistor is connected to the drain of the first MOS transistor, the source of the second MOS transistor is connected to the source of the first MOS transistor, and the gate of the second MOS transistor is connected to the gate of the first MOS transistor through a second capacitance element, and wherein the drain of the fourth MOS transistor is connected to the drain of the third MOS transistor, the source of the fourth MOS transistor is connected to the source of the third MOS transistor, and the gate of the fourth MOS transistor is connected to the gate of the third MOS transistor through a third capacitance element.

9. The semiconductor integrated circuit device according to claim 1, further comprising one or more fifth MOS transistors connected in parallel with the first and second MOS transistors, wherein the control unit on/off-controls the second and fifth MOS transistors, so as to enable an equivalent gate width based on the first, second and fifth MOS transistors to be increased and decreased.

10. The semiconductor integrated circuit device according to claim 2, further comprising:
one or more fifth MOS transistors connected in parallel with the first and second MOS transistors; and
one or more sixth MOS transistors connected in parallel with the third and fourth MOS transistors;
wherein the control unit on/off-controls the first to sixth MOS transistors, so as to enable an equivalent gate width based on the first to sixth MOS transistors to be increased and decreased.

11. The semiconductor integrated circuit device according to claim 3, wherein the control unit changes the gate potential of the second MOS transistor on the basis of the information including an oscillation frequency, thereby turning on and off the second MOS transistor.

12. The semiconductor integrated circuit device according to claim 4, wherein the control unit changes the gate potentials of the second and fourth MOS transistors on the basis of the information including an oscillation frequency, thereby turning on and off the second and fourth MOS transistors.

13. A frequency synthesizer comprising:
a voltage-controlled oscillator composed of a resonance circuit having a resonance frequency based on the capacitance of a variable-capacitance unit capacitance of which varies according to information including an oscillation frequency and of an oscillation unit including oscillation transistors connected to the resonance circuit and configured to deliver an oscillation output having the resonance frequency; and
a control unit configured to be provided with oscillation frequency information to be supplied to a PLL circuit configured to generate information including the oscillation frequency on the basis of the output of the voltage-controlled oscillator and the oscillation frequency information, so as to variable-control the gate widths of the oscillation transistors constituting the oscillation unit.

14. The frequency synthesizer according to claim 13, wherein the oscillation unit includes, as the oscillation transistors:
a first MOS transistor connected to the resonance circuit; and
a second MOS transistor the drain of which is connected to the drain of the first MOS transistor, the source of which is connected to the source of the first MOS transistor, and the gate of which is connected to the gate of the first MOS transistor through a capacitance element;
wherein the control unit turns on and off the second MOS transistor according to the oscillation frequency, thereby enabling an equivalent gate width based on the first and second MOS transistors to be increased and decreased.

15. The frequency synthesizer according to claim 14, wherein the first and second MOS transistors are configured to form a differential pair along with third and fourth MOS transistors, respectively.

16. The frequency synthesizer according to claim 14, wherein the variable-capacitance unit is configured by parallel-connecting a plurality of series circuits composed of first capacitances and switches.

17. The frequency synthesizer according to claim 15, wherein the variable-capacitance unit is configured by parallel-connecting a plurality of series circuits composed of first capacitances and switches.

18. The frequency synthesizer according to claim 14, further comprising one or more fifth MOS transistors connected in parallel with the first and second MOS transistors, wherein the control unit on/off-controls the second and fifth MOS transistors, so as to enable an equivalent gate width based on the first, second and fifth MOS transistors to be increased and decreased.

19. The frequency synthesizer according to claim 15, further comprising:
one or more fifth MOS transistors connected in parallel with the first and second MOS transistors; and
one or more sixth MOS transistors connected in parallel with the third and fourth MOS transistors;
wherein the control unit on/off-controls the first to sixth MOS transistors, so as to enable an equivalent gate width based on the first to sixth MOS transistors to be increased and decreased.
